(19) United States
(12) Patent Application Publication
(10) Pub. No.: US 2006/0102992 A1
(43) Pub. Date: May 18, 2006

(54) Multi-chip package

(76) Inventors: Heung-Kyu Kwon, Gyeonggi-do (KR); Se-Nyun Kim, Chungcheongnam-do (KR); Jeong-O Ha, Chungcheongnam-do (KR)

Correspondence Address: MARGER JOHNSON & MCCOLLOM, P.C., 210 SW MORRISON STREET, SUITE 400, PORTLAND, OR, 97204, US

(21) Appl. No.: 11/258,765

(22) Filed: Oct. 25, 2005

(30) Foreign Application Priority Data
Nov. 17, 2004 (KR) 2004-93861

(51) Int. Cl. H01L 23/02

(52) U.S. Cl. 257/685

(57) ABSTRACT

A multi-chip package includes a substrate having first and second substrate pads, ball pads electrically connected to the first and second substrate pads, a first chip attached on the substrate and having first chip pads flip-chip bonded to the first substrate pads, and a second chip attached on the first chip and having second chip pads wire-bonded to the second substrate pads. The second chip may have overhang portions. Solder balls may be formed on the ball pads and act as external connection terminals. A support member may be interposed between the first chip and the second chip to support the overhang portions of the second chip.

### CROSS REFERENCE TO RELATED APPLICATIONS

This U.S. non-provisional application claims benefit of priority under 35 U.S.C. § 119 of Korean Patent Application No. 2004-93861, filed on Nov. 17, 2004, the entire contents of which are incorporated herein by reference.

### BACKGROUND OF THE INVENTION

1. Field of the Invention

The present invention relates to semiconductor packages and, more particularly, to multi-chip semiconductor packages.

2. Description of the Related Art

A recent trend in the electronic industry is to manufacture reliable, light, compact, high-speed, multifunctional and high-performance electronic products at competitive costs. Multi-chip packaging techniques have been introduced to meet these demands. Multi-chip packages (MCPs) may include a plurality of semiconductor chips in a single package. MCPs may produce high integration, size reduction and/or lighter weight.

The advance of the multi-chip packaging techniques may incorporate system in package (SIP) techniques. The SIP techniques may combine all of the electronic components needed to provide a system in a single package. On the other hand, system on chip (SOC) techniques may combine all of the functions needed to provide a system in a semiconductor chip. The SIP techniques may incorporate a combination of MCP and SOC techniques.

The SIP techniques may be useful for communication products including, for example, RF telecommunications, BLUETOOTH (a protocol of a short-range radio technology developed by Intel, IBM, Nokia, Ericsson and Toshiba) modules, high-performance PC cards, or telecommunication modules of mobile phones. SIP-based MCPs may be introduced in mobile phones including international mobile telecommunications-2000 (IMT-2000) (mobile telecommunication standardization). The SIP-based MCPs may include semiconductor chips such as NAND flash memories for storing a variety of data including phone numbers, and semiconductor chips such as memory unit transistor (UT) RAMs for temporarily storing received data including video.

The SIP-based MCPs may combine at least two chips selected from high frequency chips corresponding to a radio frequency band of 800 MHz (i.e., a frequency band of mobile phones) or 1.8 GHz (i.e., a frequency band of IMT-2000), baseband chips corresponding to an intermediate frequency band of 100 MHz to 400 MHz, and memory chips including nonvolatile flash memories. Generally, a high frequency chip or a baseband chip may be attached as a lower chip on a substrate and a memory chip may be attached as an upper chip by stacking the memory chip on the lower chip.

A high frequency chip or a baseband chip as a lower semiconductor chip may be flip-chip-bonded to a substrate. A memory chip as an upper chip may be wire-bonded to the lower chip. A wire bonding method, however, may have unstable impedance characteristics. In particular, wire bonding may have undesirable inductance characteristics under high frequency. On the other hand, a flip-chip bonding method has a short interconnection distance and a fixed shape connection portion. Therefore, a flip-chip bonding method may establish stable interconnections for a high frequency chip or a baseband chip mounted on the substrate.

A memory chip may be larger in size than a high frequency chip or a baseband chip and may have overhang portions when attached as an upper chip, e.g., when stacked upon the relatively smaller high frequency or baseband chip.

FIG. 1 is a cross-sectional view of a conventional multi-chip package 100. Referring to FIG. 1, the multi-chip package 100 may comprise a substrate 150, a lower chip 110, bumps 180, an upper chip 120, wires 161, an encapsulant 170, and solder balls 181.

The substrate 150 may include a substrate body 151, first and second substrate pads 152 and 153 formed on the top surface of the substrate body 151, and ball pads 154 formed on the bottom surface of the substrate body 151. As will be appreciated, electrical connections (not shown) internal to substrate 151 couple pads 152 and 153 to ball pads 154. The first and second substrate pads 152 and 153 may provide electrical connections to the lower and upper chips 110 and 120, respectively. The ball pads 154 may provide electrical connections for the package 100 to external devices.

The lower chip 110 may be attached on the substrate 150 using a flip-chip bonding method. The lower chip 110 may have lower chip pads 112 arranged on the lower chip 110 and a first passivation layer 113 covering the lower chip 110, but leaving exposed the lower chip pads 112.

The bumps 180 may electrically connect the lower chip pads 112 of the lower chip 110 to the first substrate pads 152 of the substrate 150. The bumps may be formed of Au. A filler 190 may fill the space between the substrate 150 and the lower chip 110 to secure mounting of the lower chip 110 on the substrate 150. The filler 190 may be formed of a resin material.

The upper chip 120 may be attached on the lower chip 110 using an adhesive layer 140. The upper chip 120 may have upper chip pads 122 arranged on the upper chip 120, and a second passivation layer 123 substantially covering the upper chip 120 but leaving exposed the upper chip pads 122. The upper chip 120 may be larger in size than the lower chip 110 and thereby present overhang portions H1.

The wires 161 may electrically connect the second substrate pads 153 of the substrate 150 to the upper chip pads 122 of the upper chip 120. The wires 161 may be formed of, for example, Au.

An encapsulant 170 may seal the top surface of the substrate 150, the lower and upper chips 110 and 120, and the wires 161. The encapsulant 170 may be formed of an epoxy resin. The encapsulant 170 may protect the lower and upper chips 110 and 120, and the wires 161, from mechanical and electrical shocks.

The solder balls 181 may be formed on the ball pads 154 and act as external connection terminals of the multi-chip package 100.

Although the conventional multi-chip package 100 is generally thought to be acceptable, it is not without shortcomings. Some shortcomings may be related to a wire bonding process connecting the second substrate pads 153 to the upper chip pads 122, e.g., a process placing the wires 161.

FIG. 2 is a cross-sectional view of a wire bonding process of a conventional multi-chip package manufacturing process.

Referring to FIG. 2, a capillary 11 may move in the direction of MI in a reverse wire bonding method. The capillary 11 may apply a downward force on an upper chip pad 122 when forming a wire 161. The pressing force of the capillary 11 may warp and/or bend an upper chip 120. Further, warping or bending of the upper chip 120 may create cracks at overhang portions Hi. Such problems are more likely as the thickness of the upper chip 120 is reduced. Similar problems may also occur in a forward wire bonding method.

Further, when a high frequency chip or a baseband chip is used as a lower chip 110, electromagnetic waves, e.g., beyond that allowable or normal, may emit outward from a package or may flow inward toward a package without filtering. In either case, this may disturb the lower chip 110. This may lead to the malfunction of the lower chip 110, e.g., as by electromagnetic interference (EMI). Although the encapsulant 170 may seal the lower chip 110 as shown in FIG. 1, the encapsulant 170 may not effectively shield against passage of undesirable electromagnetic waves therethrough.

### SUMMARY OF THE INVENTION

An example embodiment of the present invention provides an improved multi-chip package reducing the likelihood of warpage or cracking of overhang portions of an upper chip.

Another example embodiment of the present invention provides an improved multi-chip package shielding electromagnetic waves when a high-frequency chip or a baseband chip is used, for example, as a lower chip.

According to an example embodiment of the present invention, a multi-chip package may comprise a substrate having at least one first substrate pad, at least one second substrate pad, and ball pads electrically connected to the first and second substrate pads. A lower chip (hereinafter referred to as a first chip) attaches on the substrate and includes first chip pads. An upper chip (hereinafter referred to as a second chip) attaches on the first chip and includes second chip pads. Solder balls may be formed on the ball pads. A support member is interposed between the first chip and the second chip to support overhang portions of the second chip. The first chip may be electrically connected to the first substrate pad. The second chip may be electrically connected to the second substrate pad. The solder balls may provide electrical connections to external devices. The support member reduces the likelihood damage, e.g., cracking of, the second chip.

The support member may include a conductive metal plate.

The support member may have an insulating base, upper and lower conductive layers formed on upper and lower surfaces of the insulating base, respectively, and conductive lines penetrating through the insulating base to electrically connect the upper and lower conductive layers.

The first chip pad may be flip-chip-bonded to the first substrate pad.

The second chip pad may be wire-bonded to the second substrate pad using a first wire.

The support member may be attached to the first chip using a first adhesive layer.

The support member may be attached to the second chip using a second adhesive layer. At least one of the first adhesive layer and the second adhesive layer may include conductive materials.

The multi-chip package may further comprise a second wire electrically connecting the support member to a third substrate pad.

The multi-chip package may further comprise a third wire electrically connecting the support member to the second chip pad.

The support member may have a base plate and support portions supporting the base plate.

The support portions of the support member may be formed of a conductive material.

One end of the support portion may be electrically connected to the base plate and the other end of the support portion may be electrically connected to the third substrate pad.

### BRIEF DESCRIPTION OF THE DRAWINGS

The example embodiments of the present invention will be readily understood with reference to the following detailed description thereof provided in conjunction with the accompanying drawings, wherein like reference numerals designate like structural elements.

FIG. 1 (Prior Art) is a cross-sectional view of a conventional multi-chip package.

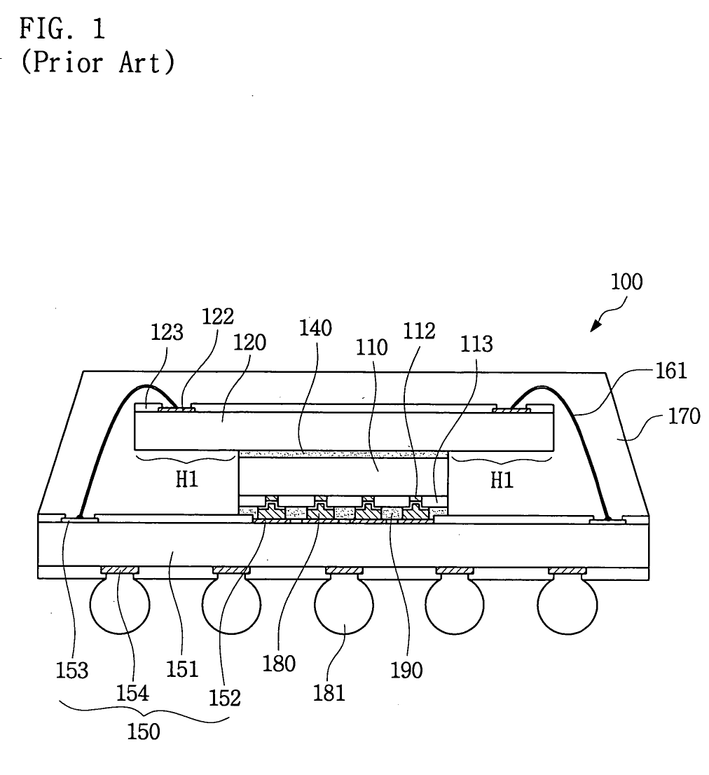

FIG. 2 (Prior Art) is a cross-sectional view of a wire bonding process of a conventional multi-chip package manufacturing process.

FIG. 3 is a cross-sectional view of a multi-chip package in accordance with an example embodiment of the present invention.

FIG. 4 is a cross-sectional view of an example of a support member.

FIG. 5 is a cross-sectional view of a multi-chip package in accordance with another example embodiment of the present invention.

FIG. 6 is a cross-sectional view of a multi-chip package in accordance with another example embodiment of the present invention.

FIG. 7 is a perspective view of a support member of FIG. 6.

These drawings are provided for illustrative purposes only and are not drawn to scale.

The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the invention.

### DETAILED DESCRIPTION OF THE EXAMPLE EMBODIMENTS

Example, embodiments of the present invention will now be described more fully with reference to the accompanying drawings. This invention may, however, be embodied in many different forms and should not be construed as limited to the example embodiments set forth herein. Rather, the disclosed embodiments are provided to present this disclosure and to convey aspects the invention to those skilled in the art. The principles and features of this invention may be employed, therefore, in varied and numerous embodiments without departing from the scope of the invention.

It should be noted that the drawings illustrate the general characteristics of methods and devices of example embodiments of this invention. These drawings are not, however, to scale and may not precisely reflect the characteristics of any given embodiment, and should not be interpreted as defining or limiting the range of values or properties of example embodiments within the scope of this invention. Rather, for simplicity and clarity of illustration, the dimensions of some of the elements are exaggerated relative to other elements.

Further, well-known structures and processes are not described or illustrated in detail to avoid obscuring the present invention. Like reference numerals are used for like and corresponding parts of the various drawings.

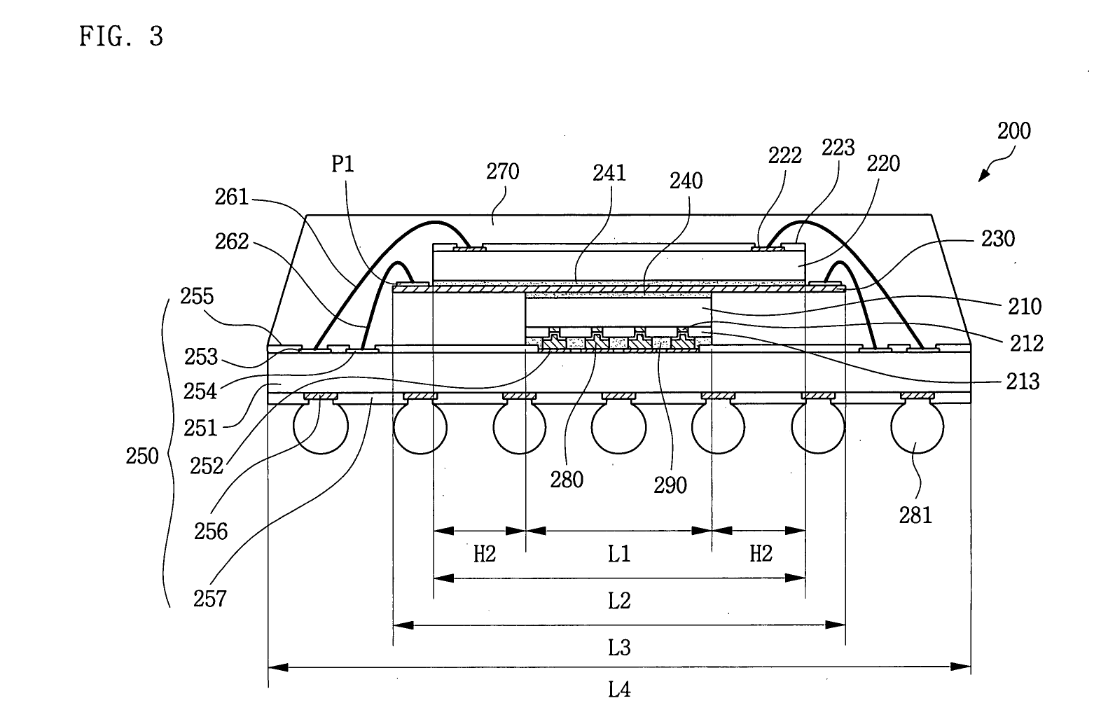

FIG. 3 is a cross-sectional view of a multi-chip package 200 in accordance with an example embodiment of the present invention.

Referring to FIG. 3, the multi-chip package 200 may comprise a substrate 250, a first chip 210, bumps 280, a filler 290, a support member 230, second wires 262, a second chip 220, first wires 261, an encapsulant 270, and solder balls 281.

The substrate 250 may include a substrate body 251, first, second and third substrate pads 252, 253 and 254, respectively, formed on the top surface of the substrate body 251, ball pads 256 formed on the bottom surface of the substrate body 251, a first insulating layer 255 formed on the top surface of the substrate body 251 exposing the first, second and third substrate pads 252, 253 and 254, and a second insulating layer 257 formed on the bottom surface of the substrate body 251 but leaving exposed the ball pads 256.

The first chip 210 may be attached on the substrate 250 using a flip-chip bonding method. The first chip 210 may have first chip pads 212 arranged on the first chip 210, and a first passivation layer 213 formed on the first chip 210 but leaving exposed the first chip pads 212.

The bumps 280 may electrically connect the first chip pads 212 of the first chip 210 to the first substrate pads 252 of the substrate 250. The bumps may be formed of, for example, Au. The first chip pads 212 may further have an under bump metalization (UBM) layer thereon for improved adhesive strength of the bumps 280. The UBM layer may include, for example, Cr/Cr—Cu/Cu/Au, Ti/Ni/Ni or Ti/Cu/Ni—V.

The filler 290 may fill the space between the substrate 250 and the first chip 210 to secure mounting of the first chip 210 on the substrate 250. The filler 290 may be formed of, for example, a resin material. The filler 290 may include a flowable underfill or a non-flowable underfill. In case of a flowable underfill, the bumps 280 may use solder bumps. The flowable underfill may be formed using a capillary action.

Alternatively, the filler 290 may include a non-conductive paste of insulating materials, or an anisotropic conductive paste of conductive materials containing, for example, Au, Ni, and Cr. If the substrate 250 is a film, the filler 290 may include a non-conductive film or an anisotropic conductive film.

The support member 230 may be attached on the first chip 210 using a first adhesive layer 240. The support member 230 may include a conductive metal plate formed of at least one selected from conductive metals such as Cu, Al, Ni, or Cr. The support member 230 may be electrically connected to the third substrate pad 254 of the substrate 250 using the second wire 262. If the third substrate pad 254 is a ground terminal, the support member 230 may act as a ground portion, e.g., to establish a shielding ground plane. Therefore, if a high frequency chip corresponding to a radio frequency band of 800 MHz (i.e., a frequency band of mobile phones) or 1.8 GHz (i.e., a radio frequency band of IMT-2000), or a baseband chip corresponding to an intermediate frequency band of 100 MHz to 400 MHz, is used as the first chip 210, the support member 230 acting as a ground portion may shield electromagnetic waves which may be emitted from the first chip 210 or directed toward the first chip 210, e.g., which may arrive from and external source.

The support member 230 may have a plating layer P1 for improved connection to the second wire 262. The plating layer P1 may be formed of, for example, Ag, Au, or Pd.

The length L3 of the support member 230 may be longer than the length L2 of the second chip 220 and may be shorter than the length L4 of the substrate 250. The support member 230 may thereby substantially cover the upper surface of the first chip 210 while supporting the second chip 220 at its lower surface. In particular, the support member 230 may substantially support the overhang portions H2 of the second chip 220.

Although this embodiment shows an example of the support member 230, the support member 230 may be not limited in this regard.

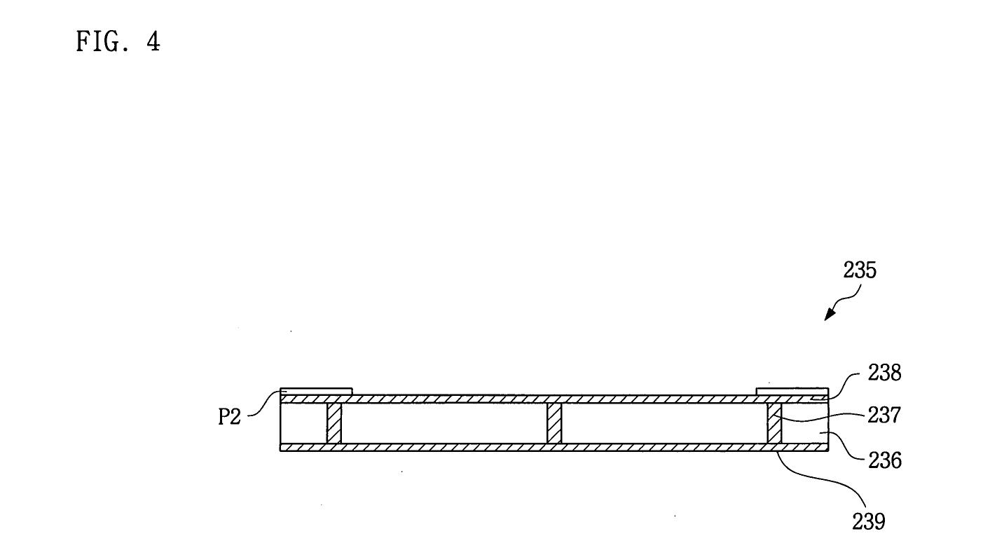

FIG. 4 is a cross-sectional view of another example of a support member 235 which can be used in place of support member 230. Referring to FIG. 4, the support member 235 may include a rigid base plate 236 formed from an insulating material, upper and lower conductive layers 238 and 239 formed on the upper and lower surfaces of the base plate 236, and conductive lines 237 penetrating through the base plate 236. Under this embodiment, the support member 235 takes mechanical strength from rigid base plate 236, which need not necessarily be electrically conductive. The upper and lower conductive layers 238 and 239 may be formed of, for example, Cu, Au, Ag, or Al. The conductive lines 237 may electrically connect the upper conductive layer 238 to the lower conductive layer 239. The support member 235 may further include a plating layer P2 for improved connection to, for example, the second wire 262. The plating layer P2 may be formed of, for example, Ag, Au, or Pd.

Returning to FIG. 3, the second wire 262 may electrically connect the support member 230 to the third substrate pad 254. The second wire 262 may be formed of, for example, Au.

The second chip 220 may be attached on the support member 230 using a second adhesive layer 241. The second chip 220 may have second chip pads 222 arranged on the second chip 220 and a second passivation layer 223 formed on the second chip 220, but leaving exposed the second chip pads 222.

The length L2 of the second chip 220 may be longer than the length L1 of the first chip 210. In such case, the second chip 220 may have overhang portions H2.

The overhang portions H2 may allow potential faults, for example warpage or cracking of the second chip 220 during wire bonding. However, with the support member 230 interposed between the first chip 210 and the second chip 220 the overhang portions H2 of the second chip 220 are supported against such faults. The support member 230 thereby reduces the likelihood of damage, e.g., warping or cracking of the second chip 220.

The first wire 261 may electrically connect the second substrate pad 253 of the substrate 250 to the second chip pad 222 of the second chip 220. The first wire 261 may be formed of, for example, Au.

The encapsulant 270 may be formed of an epoxy resin. The encapsulant 270 may seal the top surface of the substrate 250, the first and second chips 210 and 220, and the first and second wires 261 and 262 as protection against mechanical or electrical shocks.

The solder balls 281 may be formed on the ball pads 256 of the substrate 250. The solder balls 281 may serve as external connection terminals for the package 200. A UBM layer may be formed on the ball pads 256 for improved attachment of the solder balls 281.

The first and second adhesive layers 240 and 241 may be formed of insulating or conductive materials. Preferably, the first and second adhesive layers may be formed of conductive materials containing Au, Ag, Cu, Ni, Cr, or Al. If the support member 230 acts as a ground portion, e.g., by use of the second wire 262, electrical ground connection of the first and second chips 210 and 220 to the support member 230 provides improved electrical stability, e.g., shielding against electromagnetic interference.

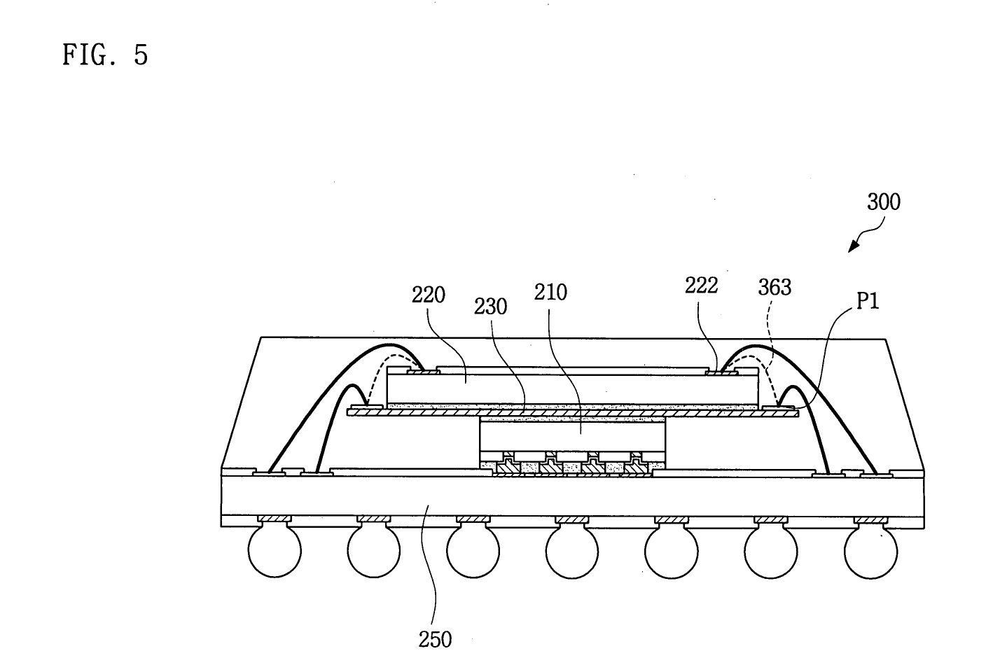

FIG. 5 is a cross-sectional view of a multi-chip package 300 in accordance with another example embodiment of the present invention.

The multi-chip package 300 may have substantially the same structure as the above-described multi-chip package 200 (FIG. 3), except for having third wires 363.

The third wires 363 may electrically connect the support member 230 to the second chip pads 222. The third wire 363 may electrically connect ground pads of the second chip pads 222 to the support member 230 to increase the number of interconnections between the ground portions. This may improve electrical stability of the multi-chip package 300.

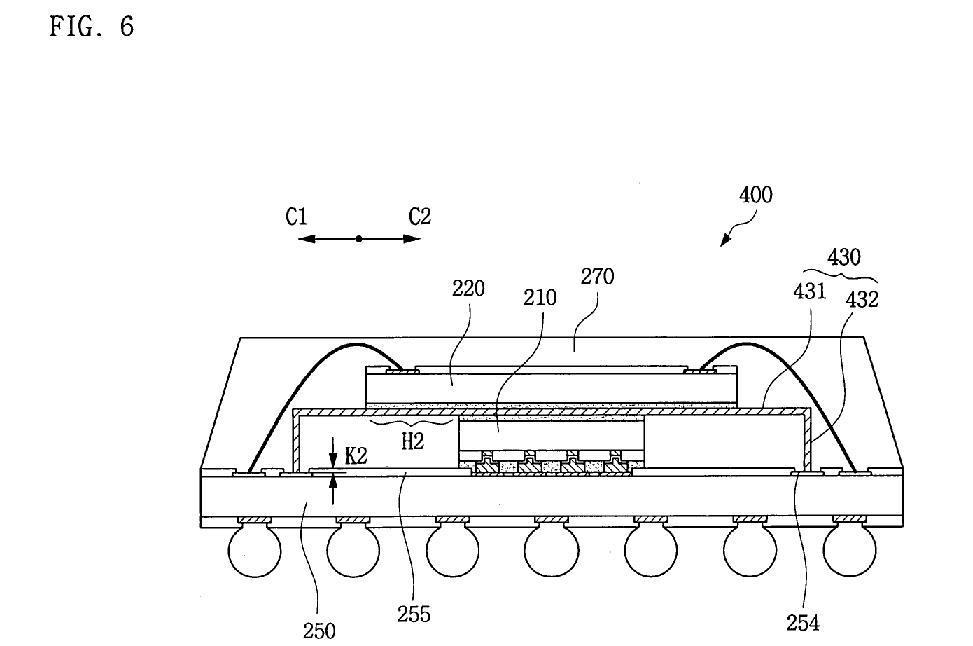

FIG. 6 is a cross-sectional view of a multi-chip package 400 in accordance with another example embodiment of the present invention. Referring to FIG. 6, the multi-chip package 400 may have a similar structure as the above-described multi-chip package 200 (FIG. 3), but having different support arrangement, e.g., support member 430.

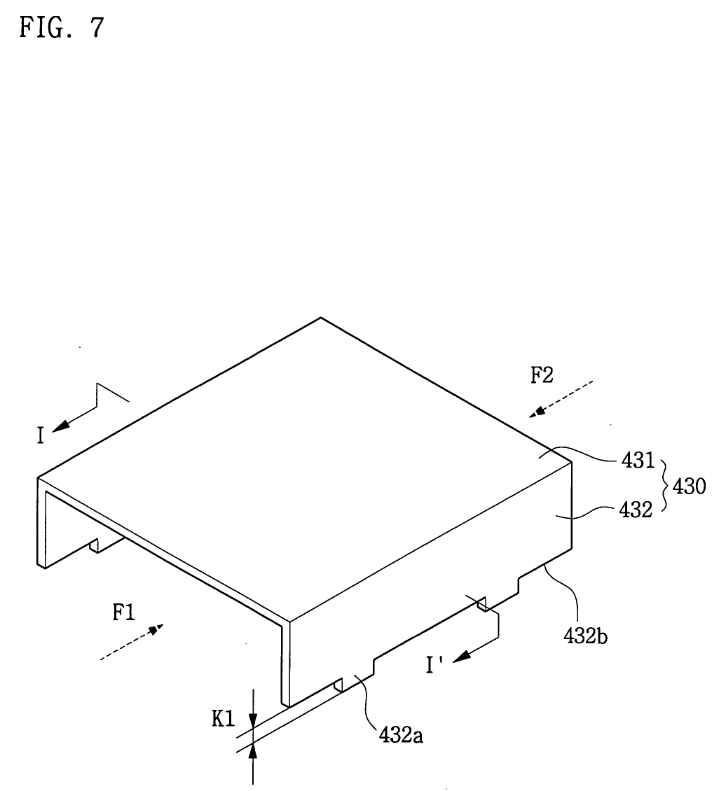

FIG. 7 is a perspective view of the support member 430 of FIG. 6. FIG. 6 is a cross-sectional view taken along the line I-I of FIG. 7. Referring to FIG. 7, the support member 430 may have a base plate 431 and support portions 432. The base plate 431 may have substantially the same structure as the support member 230 of FIG. 3, and the detailed description may be herein omitted.

The support portions 432 may be formed at opposite edges of the base plate 431. The support portions 432 may be formed integrally with the base plate 431, e.g., may be bent downward out of the plane of base plate 431. The support portions 432 may have protrusions 432a to connect to the third substrate pads 254.

When the support portions 432 are formed of conductive materials, the support portions 432 may electrically connect the base plate 431 to the third substrate pads 254, e.g., when serving as ground terminals. The support portions 432 may improve electrical stability and shield electromagnetic waves emitted or flowing in the directions Cl and C2 (FIG. 6). In this case, a resin may flow in the directions of F1 or F2 (FIG. 7) for a smooth molding process when forming the encapsulant 270.

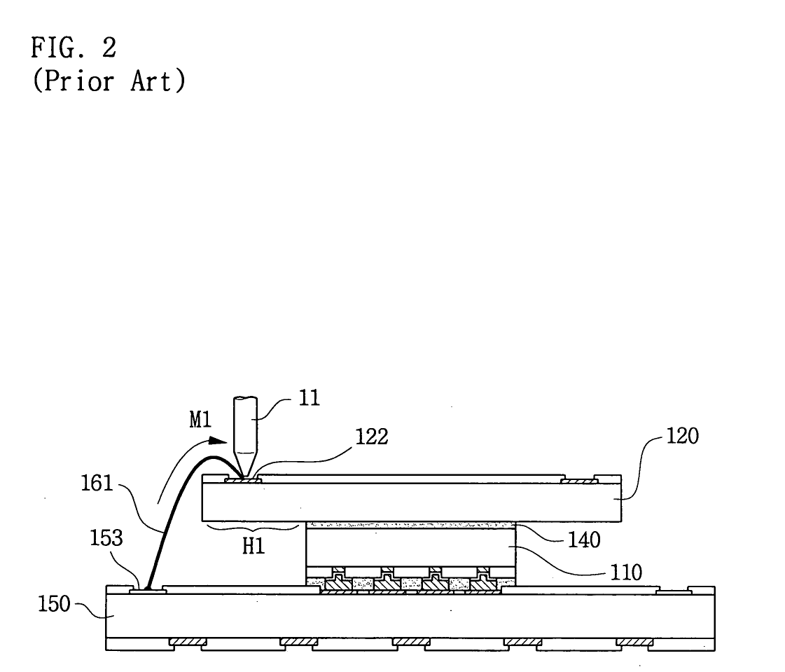

The projection height K1 of the protrusions 432a (FIG. 7) may be equal to the difference K2 (FIG. 6) in height between the third substrate pads 254 and the first insulating layer 255. If a soldering is formed between the protrusions 432a and the third substrate pads 254, the projection height K1 of the protrusions 432a may be smaller than the difference K2 in height between the third substrate pads 254 and the first insulating layer 255. A bottom surface 432b of the base plate 432 may be evenly connected to the upper surface of the first insulating layer 255. The pressing force of the capillary, such as capillary 11 of FIG. 2, may disperse over the upper surface of the insulating layer 255 through the support portions 432. Therefore, mechanical stability of the overhang portions H2 of the second chip 220 improves.

In accordance with example embodiments of the present invention, a support member may be interposed between a first chip and a second chip to support overhang portions of the second chip. The overhang portions may be protected from mechanical shocks caused by, for example, pressing force of a capillary during a wire bonding process. The support member reduces the likelihood of warpage or cracking of the second chip and thereby improves the reliability of a multi-chip package.

If the support member is connected to a package-external ground using a conductive material, the support member may shield electromagnetic waves emitted from the first chip or flowing in from the external environment, thereby reducing an EMI problem.

Although example, non-limiting embodiments of the present invention have been described in detail hereinabove, it should be understood that many variations and/or modifications of the basic inventive concepts herein taught, which may appear to those skilled in the art, will still fall within the spirit and scope of the example embodiments of the present invention as defined in the appended claims.

What is claimed is:

1. A multi-chip package comprising:
a substrate having first substrate pads and second substrate pads;
a first chip mounted on the substrate and having first chip pads to electrically connect to the first substrate pads;
a second chip mounted in relation to the first chip and having second chip pads to electrically connect to the second substrate pads, the second chip having overhang portions; and
a support member interposed between the first chip and the second chip to support the overhang portions of the second chip.

2. The package of claim 1 further comprising:
ball pads electrically connected to the first substrate pads and to the second substrate pads;and
solder balls formed on the ball pads.

3. The package of claim 1 wherein the support member includes a base plate and support portions formed at opposite edges of the base plate to extend from the base plate to the substrate.

4. The package of claim 3 wherein the support portions of the support member are conductive to electrically connect at a first end to the base plate and at a second end to third substrate pads of the substrate.

5. The package of claim 1 wherein the support member includes a conductive metal plate.

6. The package of claim 5 wherein the support member includes support portions formed at opposite edges of the metal plate to extend from the metal plate to the substrate.

7. The package of claim 6 wherein the support portions are conductive to electrically connect at a first end to the metal plate and at a second end to third substrate pads of the substrate.

8. The package of claim 1 wherein the support member includes an insulating base, upper and lower conductive layers formed on upper and lower surfaces of the insulating base, and conductive lines to electrically connect the upper conductive layer to the lower conductive layer.

9. The package of claim 8 wherein at least one of the upper and lower conductive layers is electrically connected to third substrate pads of the substrate.

10. The package of claim 8 wherein at least one of the upper and lower conductive layers is electrically connected to the second chip pads of the second chip.

11. The package of claim 1 wherein the first substrate pads are flip-chip bonded to the first chip pads.

12. The package of claim 11 wherein the support member includes a base plate and support portions formed at opposite edges of the base plate to extend from the base plate to the substrate.

13. The package of claim 12 wherein the base plate is conductive and the support portions are conductive to electrically connect at a first end thereof to the base plate and at a second end thereof to third substrate pads of the substrate.

14. The package of claim 1 further comprising first wires to electrically connect the second chip pads to the second substrate pads.

15. The package of claim 14 wherein the support member is conductive and the package further comprises second wires to electrically connect the support member to third substrate pads of the substrate.

16. The package of claim 1 wherein the support member is conductive, attached to the first chip using a first adhesive layer, attached to the second chip using a second adhesive layer; and at least one of the first adhesive layer and the second adhesive layer is conductive.

17. The package of claim 16 wherein the support member electrically couples to third substrate pads of the substrate.

18. The package of claim 16 wherein the support member includes a base plate and support portions formed at opposite edges of the base plate to extend from the base plate to the substrate.

19. The package of claim 18 wherein the base plate is conductive and the support portions are conductive to electrically connect at a first end thereof to the base plate and at a second end thereof to third substrate pads of the substrate.

20. The package of claim 16 wherein the support member is electrically connectable the second chip pads.

21. A multi-chip package comprising:
a first integrated circuit having a first active surface presenting first pads thereon and a first back surface opposite the first active surface, the first integrated circuit having a first length along a first axis;
a second integrated circuit having a second active surface presenting second pads thereon and a second back surface opposite the second active surface, the second integrated circuit having a second length along a second axis;
a substrate including third pads, the first active surface being mounted on a first surface of the substrate; and
a planar support member having a third length along a third axis, the first back surface being mounted on a first surface of the support member, the second back surface being mounted on a second surface of the support member, the second pads being electrically connectable to the third pads of the substrate.

22. The multi-chip package according to claim 21 wherein the first axis, second axis, and third axis are in parallel relation and the second length is greater than the first length.

23. The multi-chip package according to claim 22 wherein the third length is greater than the first length.

24. The multi-chip package according to claim 21 wherein the first axis, second axis, and third axis are in parallel relation and the second length is greater than the first length and the second length is substantially equal to the third length.

25. The multi-chip package according to claim 21 wherein the first axis, second axis, and third axis are in parallel relation, the second length is greater than the first length and the third length is greater than the second length.

26. The multi-chip package according to claim 21 wherein the support member includes a conductive portion electrically connectable to act as a shield.

27. The multi-chip package according to claim 26 wherein the shield is a ground plane.

28. The multi-chip package wherein an upper integrated circuit chip overhangs a lower integrated circuit chip, the multi-chip package comprising;
a support member interposable between the first integrated circuit chip and the second integrated circuit chip to support overhang portions of said upper integrated circuit chip.

29. The multi-chip package according to claim 28 wherein the support member is formed to resist a force directed into the upper chip during a wire bonding process.

30. The multi-chip package according to claim 28 wherein the support member is conductive and electrically connectable to establish the support member as an electromagnetic shield.

31. The multi-chip package according to claim 30 wherein the support member is electrically connectable to the upper chip.
